(19) United States
(12) Patent Application Publication
(10) Pub. No.: US 2010/0244206 A1
(43) Pub. Date: Sep. 30, 2010

(54) METHOD AND STRUCTURE FOR THRESHOLD VOLTAGE CONTROL AND DRIVE CURRENT IMPROVEMENT FOR HIGH-K METAL GATE TRANSISTORS

(75) Inventors: Huiming Bu, Glenmont, NY (US); Michael P. Chudzik, Danbury, CT (US); Wei He, Fishkill, NY (US); Rashmi Jha, Toledo, OH (US); Young-Hee Kim, Mohegan Lake, NY (US); Siddarth A. Krishnan, Peekskill, NY (US); Renee T. Mo, Briarcliff Manor, NY (US); Naim Moumen, Walden, NY (US); Wesley C. Natzle, New Palts, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: International Business Machines Corporation, Armonk, NY (US)

(21) Appl. No.: 12/414,794

(22) Filed: Mar. 31, 2009

(51) Int. Cl. H01L 23/00; H01L 21/314

(52) U.S. Cl. 257/635; 438/763; 257/E21.266; 257/E23.002

(57) ABSTRACT

A method of forming a device includes providing a substrate, forming an interfacial layer on the substrate, depositing a high-k dielectric layer on the interfacial layer, depositing an oxygen scavenging layer on the high-k dielectric layer and performing an anneal. A high-k metal gate transistor includes a substrate, an interfacial layer on the substrate, a high-k dielectric layer on the interfacial layer and an oxygen scavenging layer on the high-k dielectric layer.

### BACKGROUND OF THE INVENTION

The present invention relates generally to integrated circuits and more specifically to a method of fabricating high dielectric constant (high-k) dielectric gate structures having interface nitridation to modulate threshold voltage and improve drive current.

Integrated circuits often employ active devices known as transistors such as field effect transistors (FETs). A metal-oxide-semiconductor field effect transistor (MOSFET) includes a silicon-based substrate comprising a pair of impurity regions (i.e., source and drain junctions), spaced apart by a channel region. A gate electrode is dielectrically spaced above the channel region. The junctions can comprise dopants which are opposite in type to the dopants residing within the channel region. MOSFETs comprising n-type doped junctions are referred to as NFETs. MOSFETs comprising p-type doped junctions are referred to as PFETs. The gate electrode can serve as a mask for the channel region during the implantation of dopants into the adjacent source and drain junctions. Shallow trench isolation (STI) structures can be formed in the substrate to isolate the junctions of different MOSFETs in an integrated circuit. Further, an interlevel dielectric can be disposed across the MOSFETs of an integrated circuit to isolate the gate areas and the junctions from overlying interconnect lines. Ohmic contacts can be formed through the interlevel dielectric down to the gate areas or junctions to couple them to the interconnect lines.

The gate dielectric interposed between the channel and the gate electrode of MOSFETs was once primarily made of thermally grown silicon dioxide (oxide). Due to the need for integrated circuits having higher operating frequencies, the thickness of the oxide gate dielectric has steadily decreased to increase the gate capacitance and hence the drive current of MOSFETs. However, as the thickness of the oxide gate dielectric has decreased, leakage currents through the gate dielectric have increased, leading to reduced device reliability. As such, the oxide gate dielectric is currently being replaced with dielectrics having higher dielectric constants (k) than oxide (i.e., k>3.8). Such “high-k dielectrics” provide for increased gate capacitance without the detrimental effect of leakage current.

Typically, the threshold voltage in a high-k metal gate transistor is tuned by metal gate work-function. Due to the threshold voltage requirements for both NFETs and PFETs in CMOS applications, dual-metal integration is needed which significantly increases the process complexity and cost. Furthermore, PFET metal gates have been found to not be thermally stable in conventional gate first integration. Another way to tune the threshold voltage is by adding a capping layer on top of the high-k dielectric. However, the capping layer can significantly decrease channel mobility, thus degrading device drive current in addition to the extra process complexity and cost.

### SUMMARY OF THE INVENTION

In a first aspect of the invention, a method of forming a device includes providing a substrate. The method includes forming an interfacial layer on the substrate. The method includes depositing a high-k dielectric layer on the interfacial layer. The method further includes depositing an oxygen scavenging layer on the high-k dielectric layer. The method also includes performing an anneal.

In a further aspect of the invention, a structure includes a substrate. The structure includes an interfacial layer on the substrate. The structure further includes a high-k dielectric layer on the interfacial layer. The structure also includes an oxygen scavenging layer on the high-k dielectric layer.

### BRIEF DESCRIPTION OF THE DRAWINGS

The present invention is described in the detailed description below, in reference to the accompanying drawings that depict non-limiting examples of exemplary embodiments of the present invention.

FIG. 1 shows processing steps and a final structure in accordance with an embodiment of the invention; and

FIG. 2 shows processing steps and a final structures in accordance with an alternate embodiment of the invention.

### DETAILED DESCRIPTION OF THE INVENTION

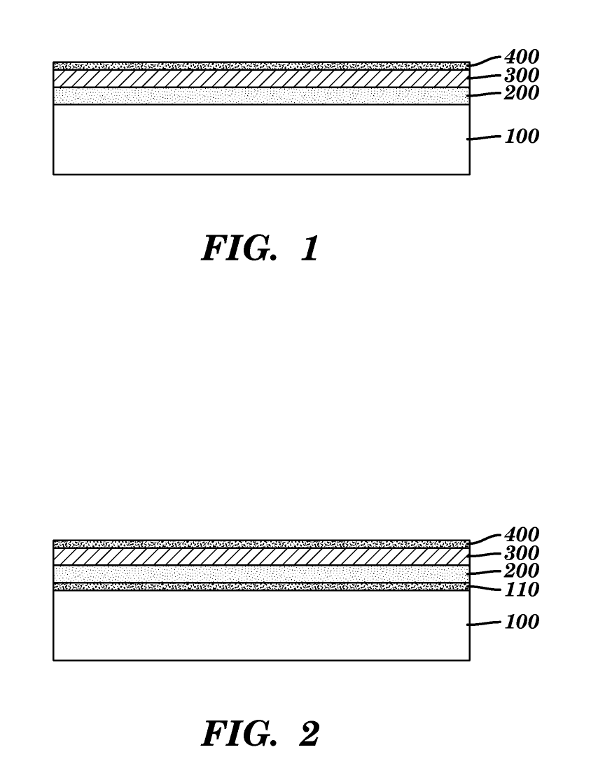

Referring to FIG. 1, a bulk substrate 100 is obtained. Bulk substrate 100, may include, but is not limited to materials chosen from single crystalline silicon, silicon-germanium (SiGe), germanium (Ge), gallium arsenide (GaAs), indium phoshide (InP) or indium antimonide (InSb) that has been slightly doped with n-type or p-type dopants. Alternatively, a semiconductor layer can be formed upon an insulation layer to create a silicon-on-insulator (SOI) or equivalent SiGe on insulator, Ge on insulator or III-V (such as GaAs, InP, InSb) on insulator structures. A gate pre-clean may be performed on a surface of the substrate 100.

A plasma nitridation process is used to form a nitridized interfacial layer 200. The plasma nitridation process may be performed at about room temperature to 500° C., about 1 milliTorr (mT) to 1 atmosphere (atm) pressure, about 10 watts (W) to 2000 W and may use nitrogen (N2) or ammonia (NH3). Nitridized interfacial layer 200 may include, but is not limited to oxide, nitride, oxynitride and nitrided oxide. Nitridized interfacial layer 200 may have a thickness of approximately 3 Å to 20 Å. The nitrogen dose may be in the range of 2E14 to 3E15 at/cm2. Alternatively, a thermal nitridation process may be used to form nitridized layer 200. The thermal nitridation process may be performed at about 700° C. or above process temperature and may use a nitrogen source, such as ammonia (NH3). This process may optionally be followed by oxidation with oxygen (O2) or other oxygen source at about 700° C. or above. Nitridized interfacial layer 200 may eventually underlie the gate. Nitridized interfacial layer 200 provides a threshold voltage decrease and improves the drive current and the mobility of high-k metal gate FETs.

Subsequently, a high-k dielectric layer 300 is deposited on top of nitridized interfacial layer 200. High-k dielectric layer 300 may have a thickness of approximately 10 Å to 60 Å. High-k dielectric layer 300 may be deposited by any known or later developed methods including, but not limited to chemical vapor deposition (CVD) or atomic layer deposition (ALD) as the gate dielectric. High-k dielectric layer 300 may include, but is not limited to hafnium oxide (HfO2), hafnium silicon oxynitride (HfSiON), tantalum oxide (Ta2O5), aluminum oxide (Al2O3), zirconium oxide (ZrO2), titanium oxide (TiO2) and combinations comprising at least one of the foregoing dielectrics.

Next, an oxygen scavenging layer 400 is deposited on the high-k dielectric layer. Oxygen scavenging layer 400 may have a thickness of approximately 1 Å to 20 Å. Oxygen scavenging layer 400 may be deposited by any known or later developed methods including, but not limited to chemical vapor deposition (CVD), physical vapor deposition (PVD) or atomic layer deposition (ALD). Oxygen scavenging layer 400 may include, but is not limited to Lanthanide metal, Rare Earth metal, TiN—particularly Ti rich TiN, Group 2 elements or Group 3 elements. Oxygen vacancies within the high-k dielectric layer 300 created by the deposition of the oxygen scavenging layer 400 consume the top surface of the underlying oxide, nitride, oxynitride or nitrided oxide interfacial layer 200.

An anneal is then performed. An O2 or N2 ambient or sequence of each may be performed. The anneal temperature may be above 900° C.

Optionally the process can include gate formation before the anneal. Optionally a first anneal can occur before gate formation and a second anneal occurs after gate formation.

Referring to FIG. 2, in an alternate embodiment of the invention, a base oxide layer 110 may be formed on substrate 100 prior to the plasma or thermal nitridation. Base oxide layer 110 may have a thickness of approximately 3 Å to 20 Å. Base oxide layer 110 may be deposited or grown by any known or later developed processes. The remaining steps are the same as described in the first embodiment.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method of forming a device, comprising:
providing a substrate;
forming an interfacial layer on the substrate;
depositing a high-k dielectric layer on the interfacial layer;
depositing an oxygen scavenging layer on the high-k dielectric layer; and
performing an anneal.

2. A method according to claim 1, wherein the interfacial layer is formed by plasma nitridation

3. A method according to claim 1, wherein the interfacial layer is formed by thermal nitridation.

4. A method according to claim 1, wherein the interfacial layer is selected from the group consisting of: oxide, nitride, oxynitride and nitrided oxide.

5. A method according to claim 1, wherein the interfacial layer has a thickness of approximately 3 Å to 20 Å.

6. A method according to claim 1, wherein the nitrogen dose in the interfacial layer is approximately 2E14 to 3E15 at/cm2.

7. A method according to claim 1, wherein the high-k dielectric layer is deposited by CVD or ALD as a gate dielectric.

8. A method according to claim 7, wherein the high-k dielectric layer is selected from the group consisting of: hafnium oxide (HfO2), hafnium silicon oxynitride (HfSiON), tantalum oxide (Ta2O5), aluminum oxide (Al2O3), zirconium oxide (ZrO2) and titanium oxide (TiO2).

9. A method according to claim 8, wherein the high-k dielectric layer has a thickness of approximately 10 Å to 60 Å.

10. A method according to claim 1, wherein the oxygen scavenging layer is selected from the group consisting of: lanthanide metal, rare earth metal, titanium rich (Ti-rich) titanium nitride (TiN), Group 2 elements and Group 3 elements.

11. A method according to claim 1, wherein the annealing step is performed at a temperature of approximately 900° C. or greater.

12. A method according to claim 1, wherein gate formation occurs before the annealing step.

13. A method according to claim 12, wherein the annealing step includes performing a first anneal before gate formation and performing a second anneal after gate formation.

14. A method of forming a device, comprising:
providing a substrate;
forming a base oxide layer on the substrate;
forming an interfacial layer on the substrate;
depositing a high-k dielectric layer on the interfacial layer;
depositing an oxygen scavenging layer on the high-k dielectric layer; and
performing an anneal.

15. A method according to claim 14, wherein the interfacial layer is deposited by plasma nitridation.

16. A method according to claim 14, wherein the interfacial layer is deposited by thermal nitridation.

17. A method according to claim 4, wherein the interfacial layer is selected from the group consisting of: oxide, nitride, oxynitride and nitrided oxide.

18. A method according to claim 4, wherein the base oxide layer has a thickness of approximately 3 Å to 20 Å.

19. A structure, comprising:
a substrate;
an interfacial layer on the substrate;
a high-k dielectric layer on the interfacial layer; and
an oxygen scavenging layer on the high-k dielectric layer.

20. A structure according to claim 19, wherein the interfacial layer is formed by plasma nitridation or thermal nitridation.

21. A structure according to claim 20, wherein the interfacial layer is selected from the group consisting of: oxide, nitride, oxynitride and nitrided oxide.

22. A structure according to claim 19, wherein the nitrogen dose in the interfacial layer is approximately 2E14 to 3E15 at/cm2.

23. A structure according to claim 19, wherein the high-k dielectric layer is selected from the group consisting of: hafnium oxide (HfO2), hafnium silicon oxynitride (HfSiON), tantalum oxide (Ta2O5), aluminum oxide (Al2O3), zirconium oxide (ZrO2) and titanium oxide (TiO2).

24. A structure according to claim 19, wherein the oxygen scavenging layer is selected from the group consisting of: lanthanide metal, rare earth metal, titanium rich (Ti-rich) titanium nitride (TiN), Group 2 elements and Group 3 elements.

25. A structure according to claim 19, wherein the interfacial layer has a thickness of approximately 3 Å to 20 Å, the high-k dielectric layer has a thickness of approximately 10 Å to 60 Å and the oxygen scavenging layer has a thickness of approximately 1 Å to 20 Å.
